(19) United States
(12) Patent Application Publication
(10) Pub. No.: US 2025/0279292 A1
(43) Pub. Date: Sep. 4, 2025

(54) CONDITION DETERMINATION SUPPORT APPARATUS AND CONDITION DETERMINATION SUPPORT METHOD

(71) Applicant: Tokyo Electron Limited, Tokyo (JP)

(72) Inventors: Hiroshi NISHIHATA, Koshi City (JP); Koudai HIGASHI, Koshi City (JP)

(73) Assignee: Tokyo Electron Limited, Tokyo (JP)

(21) Appl. No.: 19/068,085

(22) Filed: Mar. 3, 2025

(30) Foreign Application Priority Data
Mar. 4, 2024 (JP) 2024-032356
Jan. 21, 2025 (JP) 2025-008631

(51) Int. Cl. H01L 21/67; G01N 21/88; G01N 21/94

(52) U.S. Cl. CPC H01L 21/67051; G01N 21/8806; G01N 21/94; H01L 21/67253

(57) ABSTRACT

A condition determination support apparatus supports determination of conditions of whether to perform a recovery processing of cleaning a flow path, through which a processing liquid flows within a substrate processing apparatus, to remove foreign substances from the flow path. The condition determination support apparatus includes a parameter calculator for calculating parameters required to determine the conditions of whether to perform the recovery processing based on accumulation data acquired by accumulating an intensity of emitted light at the time of radiating light to the flow path whenever the processing liquid is supplied to a substrate.

### CROSS-REFERENCE TO RELATED APPLICATIONS

This application claims the benefit of Japanese Patent Application No. 2024-032356 filed on Mar. 4, 2024 and Japanese Patent Application No. 2025-008631 filed on Jan. 21, 2025, the entire disclosures of each are incorporated herein by reference.

### TECHNICAL FIELD

The exemplary embodiments described herein pertain generally to a condition determination support apparatus and a condition determination support method.

### BACKGROUND

There is known a substrate processing apparatus configured to optically detect foreign substances in a supply channel through which a fluid to be supplied to a substrate flows (see, for example, Patent Document 1). The substrate processing apparatus described in Patent Document 1 can detect foreign substances in each of a plurality of supply channels and specify which channel of the channels is the cause of a foreign substance.

### PRIOR ART DOCUMENT

Patent Document 1: Japanese Patent Laid-open Publication No. 2020-119996

### SUMMARY

In one exemplary embodiment, a condition determination support apparatus is configured to support determination of conditions of whether to perform a recovery processing of cleaning a flow path, through which a processing liquid flows within a substrate processing apparatus, to remove foreign substances from the flow path. The condition determination support apparatus includes a parameter calculator configured to calculate parameters required to determine the conditions of whether to perform the recovery processing based on accumulation data acquired by accumulating an intensity of emitted light at the time of radiating light to the flow path whenever the processing liquid is supplied to a substrate.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a schematic plan view illustrating a configuration of a wafer processing system;

FIG. 2 is a schematic front view illustrating the configuration of the wafer processing system;

FIG. 3 is a schematic diagram illustrating an example of a liquid processing unit;

FIG. 4 is a schematic diagram illustrating an example of a processing liquid supply of the liquid processing unit;

FIG. 5 is a schematic side view illustrating an example of a foreign substance detection unit;

FIG. 6 is a schematic perspective view illustrating an example of the foreign substance detection unit;

FIG. 7 is another schematic perspective view illustrating the example of the foreign substance detection unit;

FIG. 8 is a block diagram illustrating an example of a condition determination support apparatus;

FIG. 9 is a diagram illustrating an example of an electrical signal acquired when a processing liquid per one time is supplied;

FIG. 10 is a diagram illustrating an example of counting foreign substances by using the acquired electrical signal;

FIG. 11 is a graph illustrating an example of time series data of a count value;

FIG. 12 is a graph illustrating an example of time series data in a case where it is determined that a fault value is included in the count value;

FIG. 13 is a graph illustrating an example of particle size data;

FIG. 14 is a graph illustrating an example of updated time series data;

FIG. 15 is a diagram illustrating an example of a hardware configuration of a controller;

FIG. 16 is a flowchart illustrating an example of a condition determination support method;

FIG. 17 is a flowchart illustrating an example of the condition determination support method;

FIG. 18 is a flowchart illustrating an example of a foreign substance detection method;

FIG. 19 is a schematic diagram illustrating an example of a display screen at the time of supporting condition determination;

FIG. 20 is a schematic diagram illustrating an example of a display screen at the time of supporting condition determination; and

FIG. 21 is a schematic diagram illustrating an example of a display screen at the time of supporting condition determination.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a condition determination support apparatus according to one or more embodiments of the present disclosure will be described with reference to the drawings. Note that, in the description, the same reference signs are given to components having substantially the same functional configurations to omit duplicate explanations.

### [Wafer Processing System]

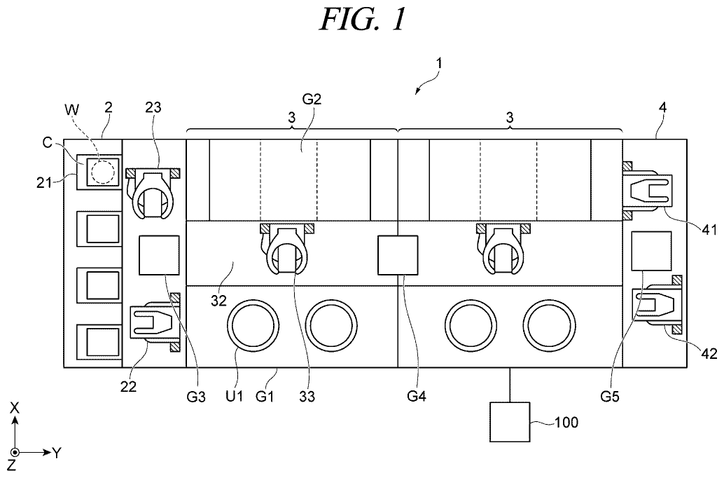

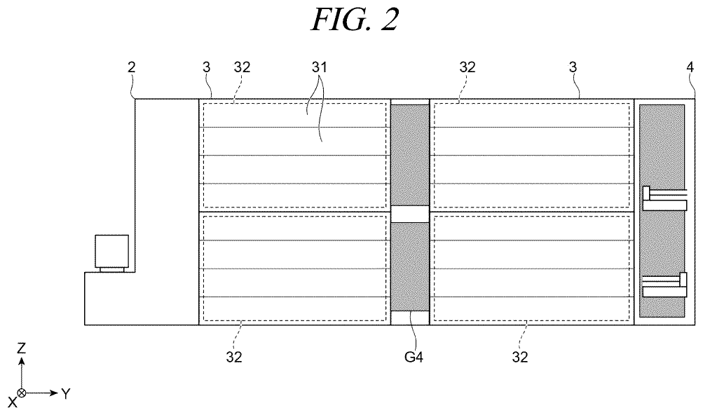

First, a wafer processing system as a substrate processing apparatus according to one or more embodiments of the present disclosure will be described. FIG. 1 and FIG. 2 are a plan view and a front view schematically illustrating a configuration of a wafer processing system 1. According to one or more embodiments of the present disclosure, a description will be given by way of an example in which the wafer processing system 1 is a photolithography processing system that performs a resist film formation processing and a development processing on a wafer W (substrate).

As illustrated in FIG. 1, the wafer processing system 1 includes a cassette station 2 where a cassette C accommodating a plurality of wafers W is carried-in and carried-out and a processing station 3 having a plurality of various processing apparatuses to perform predetermined processes on the wafer W. The processing station 3 is an example of a substrate processing apparatus. The wafer processing system 1 has a configuration in which the cassette station 2, the processing station 3, and an interface station 4 that delivers the wafer W to and from an exposure apparatus (not illustrated) adjacent thereto on the opposite side from the processing station 3 are integrally connected. Also, as illustrated in FIG. 1, two processing stations 3 are provided between the cassette station 2 and the interface station 4, but only one processing station 3 may be provided, or three or more processing stations 3 may be provided.

The cassette station 2 is equipped with a plurality of cassette placing tables 21 and wafer transfer devices 22 and 23. In the cassette station 2, the wafer W is transferred between the cassette C placed on the cassette placing table 21 and the processing station 3 by the wafer transfer device 22 or the wafer transfer device 23. Therefore, the wafer transfer devices 22 and 23 may have drive mechanisms for respective directions such as X-axis direction, Y-axis direction, vertical direction, and rotational direction around a vertical axis (θ-direction) as needed, or may have a drive mechanism for all directions.

At least one of the wafer transfer devices 22 and 23 is capable of delivering the wafer W to and from the cassette C and is also capable of delivering the wafer W to and from the processing station 3. Further, the delivery operation of the wafer W to and from the processing station 3 involves, for example, delivering the wafer W to and from a third block G3 having a delivery device accessible by a wafer transfer device 33 in the processing station 3 to be described later. The third block G3 may be equipped with a plurality of delivery devices (not illustrated) arranged in the vertical direction.

Furthermore, an inspection device (not illustrated) configured to inspect the wafer W may be provided at a position accessible by one of the wafer transfer devices 22 and 23.

The processing station 3 is equipped with a plurality of blocks, for example, three blocks such as a first block G1, a second block G2, and a fourth block G4. Also, as illustrated in FIG. 2, a plurality of layers 31 including the first block G1 and the second block G2 is stacked in the vertical direction. For example, the first block G1 is provided on the front side of the processing station 3 (on the negative side of the X-axis direction in FIG. 1), and the second block G2 is provided on the rear side of the processing station 3 (on the positive side of the X-axis direction in FIG. 1). The fourth block G4 is provided on the side of the processing station 3 toward the interface station 4 (on the positive side of the Y-axis direction in FIG. 1) or at a connection portion with the other adjacent processing station 3. The fourth block G4 may have a plurality of delivery devices arranged in the vertical direction. Further, the third block G3 may be provided in the processing station 3.

In the first block G1, a plurality of processing apparatuses, for example, a non-illustrated film forming apparatus for patterning and a non-illustrated developing apparatus, is arranged. The film forming apparatus for patterning may include, for example, an anti-reflection film forming apparatus as well as a resist film forming apparatus. For example, a plurality of processing apparatuses is arranged in a horizontal direction. Furthermore, the number, arrangement, and type of these processing apparatuses may be selected as required. In the first block G1, a liquid processing unit U1 as an example of a film forming apparatus for patterning may be arranged.

The film forming apparatus for patterning and the developing apparatus perform, for example, a supply of a predetermined processing liquid or a supply of a predetermined gas onto the wafer W. In this way, the film forming apparatus for patterning forms a resist film to be used as a mask when forming a pattern on an underlying film or forms an anti-reflection film or the like for facilitating a light radiation processing, such as an exposure processing. Also, in the developing apparatus, a portion of an exposed resist film is removed to form an uneven shape as the mask.

For example, in the second block G2, heat treatment apparatuses (not illustrated) which perform heat treatment, such as heating and cooling, of the wafer W are provided in the vertical direction and the horizontal direction. Although not all illustrated, the second block G2 is also equipped with a hydrophobizing apparatus that performs a hydrophobizing processing to increase attachment of a resist solution to the wafer W and a peripheral exposure apparatus that exposes an outer periphery of the wafer W, which are arranged in the vertical direction (in the Z-direction in FIG. 2) and the horizontal direction. The numbers and arrangements of the heat treatment apparatuses, hydrophobizing apparatus, and peripheral exposure apparatus may also be arbitrarily selected.

A wafer transfer area 32 is formed between the first block G1 and the second block G2 when viewed from the top as illustrated in FIG. 1. For example, the wafer transfer device 33 is located in the wafer transfer area 32.

The wafer transfer device 33 includes, for example, a transfer arm that is movable in the X-axis direction, the Y-axis direction, the θ-direction, and the vertical direction. The wafer transfer device 33 may move inside the wafer transfer area 32 to transfer the wafer W to predetermined devices in the first block G1, the second block G2, the third block G3, and the fourth block G4 around thereof. When a plurality of processing stations 3 is provided as illustrated in FIG. 1, the wafer transfer device 33 provided in the processing station 3 located on the interface station 4 side may transfer the wafer W to a predetermined device in a fifth block G5 to be described later in addition to the first block G1, the second block G2, and the fourth block G4.

For example, a plurality of wafer transfer devices 33 may be arranged in the vertical direction. One wafer transfer device 33 may transfer the wafer W to predetermined devices located at heights of upper layers 31, among the plurality of vertically stacked layers 31 (see FIG. 2). Another wafer transfer device 33 may transfer the wafer W to predetermined devices located at heights of layers 31 below the upper layers 31. A plurality of wafer transfer areas 32 is provided to enable the transfer of the wafer W in this manner. Also, the number of wafer transfer devices 33 and the number of layers 31 corresponding to one wafer transfer device 33 may be arbitrarily selected. For example, the wafer transfer device 33 may be provided for each layer 31.

Further, a shuttle transfer device (not illustrated) may be provided in the wafer transfer area 32, the first block G1, or the second block G2. The shuttle transfer device linearly transfers the wafer W between a space adjacent to one side of the processing station 3 and another space adjacent to the opposite side.

The interface station 4 is equipped with the fifth block G5 having a plurality of delivery devices and wafer transfer devices 41 and 42. The interface station 4 transfers the wafer W by using the wafer transfer device 41 or the wafer transfer device 42 between an exposure apparatus and the fifth block G5 to which the wafer W is delivered by the wafer transfer device 33. Therefore, the wafer transfer devices 41 and 42 may have drive mechanisms for respective directions such as X-axis direction, Y-axis direction, vertical direction, and rotational direction around a vertical axis (θ-direction) as needed, or may have a drive mechanism for all directions. At least one of the wafer transfer devices 41 and 42 may support the wafer W and transfer the wafer W between the exposure apparatus and the delivery device in the fifth block G5.

A cleaning apparatus configured to clean the surface of the wafer W and the above-described peripheral exposure apparatus may be provided at positions accessible by one of the wafer transfer devices 41 and 42 in the interface station 4.

As described above, the inspection device may be provided in the cassette station 2. Alternatively, the inspection device may be provided at a position accessible by one of the transfer arms (33, 41 and 42 in FIG. 1 or FIG. 2) in each of the processing station 3 and the interface station 4.

The above-described wafer processing system 1 is equipped with a controller 100. The controller 100 is implemented by, for example, a computer, and includes a program storage (not shown). A program for controlling a processing of the wafer W in the wafer processing system 1 is stored in the program storage. Further, the program storage stores therein a program for implementing a wafer processing in the wafer processing system 1 by controlling the above-described various processing apparatuses and a driving system, such as the transfer devices. Furthermore, the programs may be recorded in a computer-readable recording medium, and may be installed from this recording medium to the controller 100. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

### [Operation of Wafer Processing System]

The wafer processing system 1 is configured as described above. Hereinafter, an example of a wafer processing performed by using the wafer processing system 1 configured as described above will be explained.

First, the cassette C accommodating the plurality of wafers W is carried into the cassette station 2 of the wafer processing system 1 and is placed on the cassette placing table 21. Then, each wafer W in the cassette C is sequentially taken out by the wafer transfer device 22 or the wafer transfer device 23 and transferred to the delivery device of the third block G3.

The wafer W transferred to the delivery device of the third block G3 is supported by the wafer transfer device 33, transferred to the hydrophobizing apparatus provided in the second block G2, and subjected to the hydrophobizing processing. Then, the wafer W is transferred to the resist film forming apparatus (e.g., the liquid processing unit U1) by the wafer transfer device 33 to form the resist film on the wafer W. Thereafter, the wafer W is transferred to the heat treatment apparatus and subjected to pre-baking. Then, the wafer W is transferred to the delivery device of the fifth block G5. Further, when a plurality of processing stations 3 is provided as illustrated in FIG. 1 and FIG. 2, before being transferred to the delivery device of the fifth block G5, the wafer W is temporarily placed on the delivery device of the fourth block G4 and is delivered between the plurality of wafer transfer devices 33. Furthermore, the wafer W may be transferred to the peripheral exposure apparatus by the wafer transfer device 33 as needed to allow a peripheral portion of the wafer W to be exposed.

The wafer W transferred to the delivery device of the fifth block G5 is transferred to the exposure apparatus by the wafer transfer devices 41 and 42 and exposed along a predetermined pattern. Also, the wafer W may be cleaned by the cleaning apparatus before exposure.

The exposed wafer W is transferred to the delivery device of the fifth block G5 by the wafer transfer devices 41 and 42. Thereafter, the wafer W is transferred to the heat treatment apparatus by the wafer transfer device 33 and subjected to post-exposure baking.

The wafer W subjected to the post-exposure baking is transferred by the wafer transfer device 33 to the developing apparatus where the wafer W is developed. The developed wafer W is transferred by the wafer transfer device 33 to a heat treatment apparatus 40 and subjected to post-baking.

Thereafter, the wafer W is transferred to the delivery device of the third block G3 by the wafer transfer device 33 and then transferred to the cassette C on the predetermined cassette placing table 21 by the wafer transfer device 22 (or the wafer transfer device 23) in the cassette station 2. In this way, a series of photolithography processes are completed.

Further, the wafer processing system of the present disclosure is not limited to the above-described configurations and operations. For example, in the configuration according to the above-described one or more embodiments of the present disclosure, the wafer W is delivered between the interface station 4 and the exposure apparatus, but the wafer processing system does not need to be directly connected to the exposure apparatus. In this case, for example, the wafer W is transferred from the cassette station 2 to the processing station 3 and subjected to a necessary processing. Then, the wafer W is returned to the cassette station 2 to be taken out of the wafer processing system. Besides, an unnecessary one of the processing apparatuses does not need to be provided in the wafer processing system, or a processing by the processing apparatus does not need to be performed.

The specific configuration of the substrate processing apparatus is not limited to the wafer processing system 1. The substrate processing apparatus is not particularly limited as long as it includes a liquid processing unit configured to supply a processing liquid to the wafer W and the controller 100 capable of controlling the liquid processing unit.

### [Liquid Processing Unit]

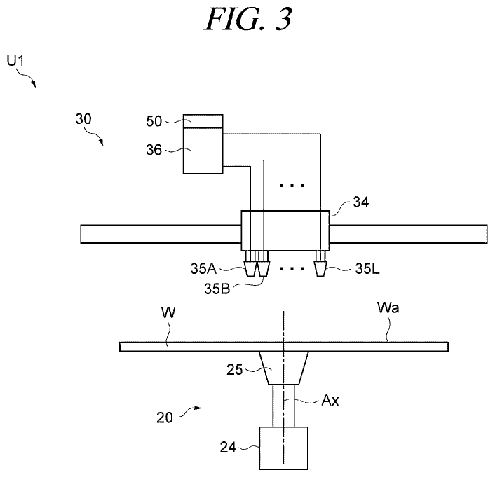

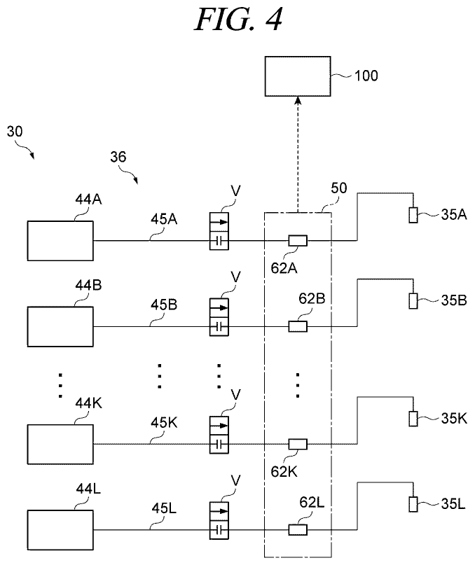

Hereinafter, an example of the liquid processing unit will be described in detail with reference FIG. 3 and FIG. 4. As illustrated in FIG. 3, the liquid processing unit U1 includes a rotation holder 20 and a processing liquid supply 30.

The rotation holder 20 holds and rotates the wafer W based on operation commands from the controller 100. The rotation holder 20 includes, for example, a holder 25 and a rotation driver 24. The holder 25 supports a central portion of the horizontally-disposed wafer W with a front surface Wa facing upwards, and holds the wafer W by, for example, vacuum suction. The rotation driver 24 is an actuator having, for example, an electric motor as a power source and rotates the holder 25 around a vertical axis Ax. As a result, the wafer W on the holder 25 rotates.

The processing liquid supply 30 discharges a processing liquid toward the front surface Wa of the wafer W to supply the processing liquid to the front surface Wa based on operation commands from the controller 100. The processing liquid supplied by the processing liquid supply 30 is a solution for substrate processing to be used for processing the wafer W. Examples of the processing liquid may include a solution (e.g., a resist) to be used for forming a resist film and a solution (e.g., a thinner) to be used for a pre-wetting processing that improves the wettability of the wafer Wa for the resist. The processing liquid supply 30 is equipped with, for example, a plurality of nozzles 35, a holding head 34, and a supply 36.

Each of the plurality of nozzles 35 discharges the processing liquid to the front surface Wa of the wafer W held on the holder 25. The plurality of nozzles 35 is disposed above the wafer W while being held by, for example, the holding head 34, and each of the plurality of nozzles 35 discharges the processing liquid downwards. The holding head 34 may be configured to be movable by a non-illustrated driver in a direction along the front surface Wa of the wafer W. The number of the plurality of nozzles 35 is not limited. However, hereinafter, there will be described an example where the processing liquid supply 30 is equipped with twelve (12) nozzles 35 (hereinafter, referred to as “nozzles 35A to 35L”).

Each of the nozzles 35A to 35L is supplied with the processing liquid from the supply 36. The nozzles 35A to 35L may be supplied with different kinds of processing liquids, respectively, from the supply 36. For example, the nozzles 35A to 35J may be supplied with different kinds of resists, respectively, from the supply 36, and the nozzles 35K and 35L may be supplied with different kinds of thinners, respectively, from the supply 36.

As illustrated in FIG. 4, the supply 36 includes a plurality of supply lines 45A to 45L and a plurality of sources 44A to 44L. The supply line 45A forms a flow path between the source 44A, which is a liquid source of a processing liquid to be supplied to the nozzle 45A (discharged from the nozzle 35A), and the nozzle 35A. The source 44A includes, for example, a bottle in which the processing liquid is stored and a pump configured to force-feed the processing liquid from the bottle to the nozzle 35A. Like the supply line 45A, the supply lines 45B to 45L form flow paths between the sources 44B to 44L, which are liquid sources of processing liquids, and the nozzles 32B to 32L, respectively.

The supply 36 further includes a plurality of opening/closing valves V provided in the plurality of supply lines 45A to 45L, respectively. Each opening/closing valve V is switched to an opened state or a closed state based on operation commands from the controller 100. When the plurality of opening/closing valves V is switched to the opened state or the closed state, the respective supply lines 45A to 45L are opened or closed. For example, when one of the opening/closing valves V is in the opened state, the processing liquid flows into a flow path of the corresponding supply line among the supply lines 45A to 45L and is discharged toward the front surface Wa of the wafer W from the corresponding nozzle among the nozzles 35A to 35L.

### [Foreign Substance Detection Unit]

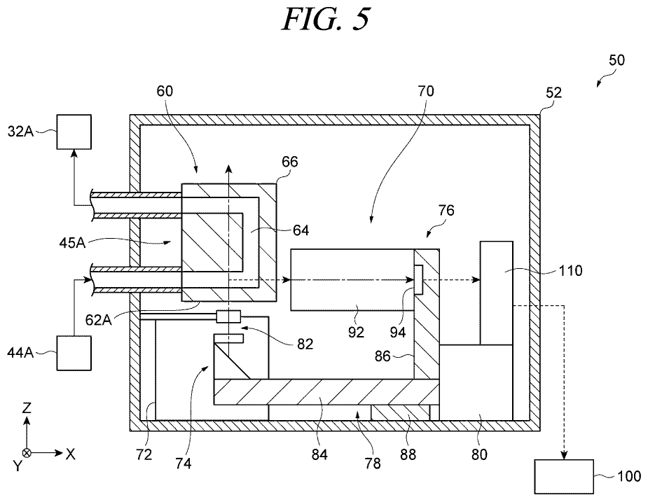

The processing station 3 is further equipped with a foreign substance detection unit (i.e., foreign substance detector) 50 configured to detect foreign substances (particles) contained in the processing liquid to be supplied to the wafer W. For example, the foreign substance detection unit 50 is configured to detect each of foreign substances in the processing liquids flowing through the flow paths of the plurality of supply lines 45A to 45L. The foreign substance detection unit 50 may be disposed near the liquid processing unit U1, or may be disposed inside a housing of the liquid processing unit U1. Some components of the foreign substance detection unit 50 may be provided between the opening/closing valves V in the flow paths of the supply lines 45A to 45L and the nozzles 35A to 35L. Hereinafter, an example of the foreign substance detection unit 50 will be described with reference to FIG. 5 to FIG. 7.

The foreign substance detection unit 50 forms flow paths (hereinafter, referred to as “processing liquid flow paths”) for the processing liquids flowing through the supply lines 45A to 45L, respectively. The foreign substance detection unit 50 receives light generated in the processing liquid flow path by radiating radiation light (e.g., a laser light) to the processing liquid flow path and thus detects foreign substances in the processing liquid flowing through the processing liquid flow path. As illustrated in FIG. 5, the foreign substance detection unit 50 is equipped with, for example, a housing 52, a flow path forming mechanism 60, and a measurer 70. The housing 52 accommodates therein the flow path forming mechanism 60 and the measurer 70.

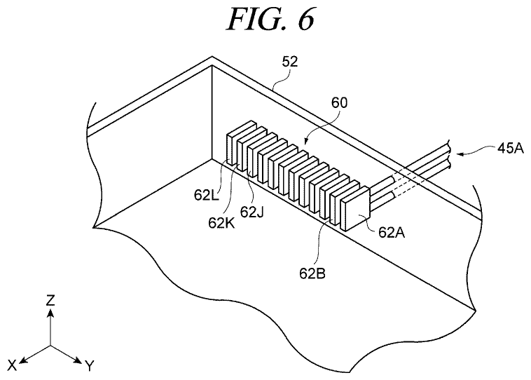

The flow path forming mechanism 60 forms a plurality of processing liquid flow paths provided in the flow paths of the supply lines 45A to 45L, respectively. Each of the plurality of processing liquid flow paths formed by the flow path forming mechanism 60 is used to detect foreign substances contained in the processing liquid flowing through the corresponding processing liquid flow path. As illustrated in FIG. 6, the flow path forming mechanism 60 is equipped with, for example, a plurality of processing liquid flow path forming mechanisms 62A to 62L. The plurality of processing liquid flow path forming mechanisms 62A to 62L has the same configuration to each other.

As illustrated in FIG. 5, the processing liquid flow path forming mechanism 62A forms the processing liquid flow path 64 in the flow path of the supply line 45A that connects the source 44A and the nozzle 35A (see FIG. 4). Ends on upstream and downstream sides of the processing liquid flow path 64 are connected to the supply line 45A. Thus, the processing liquid force-fed from the source 44A sequentially flows through a part of the flow path of the supply line 45A, the processing liquid flow path 64 corresponding to the processing liquid flow path forming mechanism 62A, and the remaining part of the flow path of the supply line 45A. Then, the processing liquid is discharged from the nozzle 35A to the front surface Wa of the wafer W.

The processing liquid flow path forming mechanism 62A includes, for example, a block main body 66 in which the processing liquid flow path 64 is formed. The block main body 66 is made of a material capable of transmitting the laser light used for detecting foreign substances. Examples of the material of the block main body 66 may include quartz and sapphire.

As described above, the processing liquid flow path forming mechanisms 62A to 62L illustrated in FIG. 6 have the same configuration to each other. Therefore, like the processing liquid flow path forming mechanism 62A, each of the processing liquid flow path forming mechanisms 62B to 62L includes the block main body 66 in which the processing liquid flow path 64 is formed.

Referring back to FIG. 5, the measurer 70 is equipped with a light source 72, a radiation device 74, a light receiving device (i.e., light receiver) 76, a holder 78, and a driver 80. The light source 72 generates a laser light as radiation light for detecting foreign substances in the processing liquid. The light source 72 emits a laser light having a wavelength of, for example, from about 400 nm to about 1000 nm and a power of, for example, from about 600 mW to about 1000 mW.

The radiation device 74 is configured to radiate the radiation light from the light source 72 toward each of the processing liquid flow paths 64 corresponding to the processing liquid flow path forming mechanisms 62A to 62L. The radiation device 74 is configured to individually radiate the radiation light toward each of the processing liquid flow paths 64 corresponding to the processing liquid flow path forming mechanisms 62A to 62L. The radiation device 74 may be disposed under the processing liquid flow path 64. The radiation device 74 is equipped with, for example, an optical member 82 configured to radiate the radiation light toward the processing liquid flow path 64 by changing a direction of the radiation light from the light source 72.

The optical member 82 includes, for example, a reflective member, a condensing lens, and a photosensitive filter. A reflective surface of the reflective member reflects the radiation light, which has been emitted in an approximately horizontal direction from the light source 72, upwards.

A part of the optical member 82 is held to be movable by the holder 78. The holder 78 is equipped with, for example, a guide rail 88 and a slider 84. The slider 84 is supported to be movable by the guide rail 88.

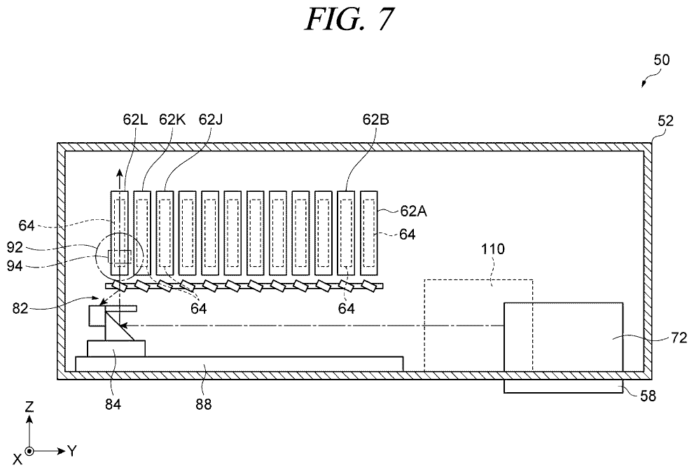

As illustrated in FIG. 7, the driver 80 moves the slider 84 along the guide rail 88 by using a power source such as an electric motor. As the slider 84 moves along the guide rail 88, the radiation device 74 (a part of the optical member 82 held by the holder 78) moves in the Y-axis direction.

The light receiving device 76 is configured to receive light emitted from the processing liquid flow path 64 when the radiation light is radiated from the radiation device 74. The light receiving device 76 includes, for example, an optical member 92 and a light receiving element 94. The optical member 92 includes, for example, the condensing lens configured to focus the light, which has been emitted from the processing liquid flow path 64, toward the light receiving element 94. A wavelength filter configured to allow only light with a specific wavelength to pass therethrough may be provided in the optical member 92. The light receiving element 94 receives the light condensed by the optical member 92 and generates an electrical signal corresponding to the received light (detection light). The light receiving element 94 includes, for example, a photodiode which performs photoelectric conversion.

The optical member 92 and the light receiving element 94 are provided on a support member 86 extending in the vertical direction. The support member 86 is connected to the slider 84. For example, a lower end of the support member 86 is connected to one end of the slider 84 opposite the other end at which the optical member 82 of the slider 84 is provided. As the slider 84 is moved by the driver 80, the optical member 92 and the light receiving element 94 move in the Y-axis direction.

With the above-described configuration, the driver 80 moves the slider 84, and, thus, both the radiation device 74 (the optical member 82 of the radiation device 74 held by the holder 78) and the light receiving device 76 move in the Y-axis direction. For example, the driver 80 moves the radiation device 74 and the light receiving device 76 between a position where each of the radiation device 74 and the light receiving device 76 faces the processing liquid flow path forming mechanism 62A and a position where each of the radiation device 74 and the light receiving device 76 faces the processing liquid flow path forming mechanism 62L.

As described above, the radiation device 74 is located under a measurement position set in the processing liquid flow path 64 and the light receiving device 76 is located at the side of the measurement position. Therefore, when the radiation light is radiated to the processing liquid flow path 64, the radiation light is scattered at the measurement position in the processing liquid flow path 64 and the light receiving device 76 receives a part of the light (scattered light). When the radiation light is radiated into the processing liquid flow path 64 through which a solution such as the processing liquid flows, scattered light is generated based on ingredients of the processing liquid regardless of the presence or absence of foreign substances. If the solution does not contain foreign substances, most of the radiation light passes through the processing liquid flow path 64. If the solution contains foreign substances, the degree of scattering of the radiation light in the processing liquid flow path 64 increases and the intensity of the light received by the light receiving device 76 (a part of the scattered light directed toward the light receiving device 76) increases compared to a case where the solution does not contain foreign substances.

### [Configuration of Condition Determination Support Apparatus]

In the liquid processing unit U1, a recovery processing may be performed. The recovery processing is a processing of cleaning a flow path to remove foreign substances from the flow path through which the processing liquid in the wafer processing system flows. For example, the recovery processing is performed to each of the supply lines 45A to 45L and can include replacing the processing liquid with new liquid, mechanical cleaning, chemical cleaning, ultrasonic cleaning, thermal cleaning, filtration and the like. Mechanical cleaning can involve physical removing debris or buildup, chemical cleaning can involve the use of solvents, detergents, acids and the like, and thermal cleaning can involve the application of heat. In the recovery processing performed to one of the supply lines 45A to 45L, the flow path in the supply line and the processing liquid flow path 64 of the corresponding processing liquid flow path forming mechanism among the processing liquid flow path forming mechanisms 62A to 62L are cleaned to remove foreign substances.

The wafer processing system 1 is equipped with a condition determination support apparatus. In an example, the foreign substance detection unit 50 is equipped with a controller 110 which performs detection of foreign substances from the electrical signal generated by the light receiving element 94, and the controller 110 functions as the condition determination support apparatus. For example, the controller 110 may be disposed inside the housing 52.

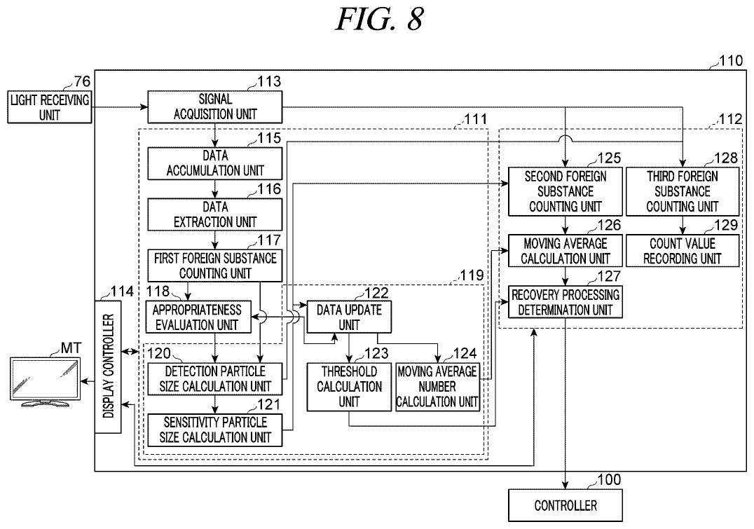

FIG. 8 is a block diagram illustrating an example of the controller 110. The controller 110 is equipped with a signal acquisition module 113, a condition determination support module 111 (condition determination support apparatus), a foreign substance detection module 112, and a display controller 114 as functional components (hereinafter, referred to as “functional blocks”). A processing implemented by these functional blocks corresponds to a processing implemented by the controller 110. The controller 110 may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

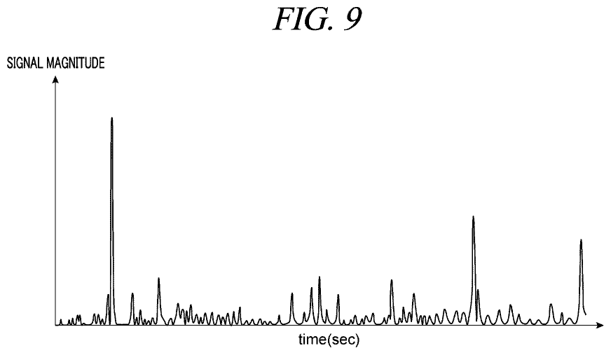

The signal acquisition module 113 acquires an electrical signal depending on the intensity of the detection light from the light receiving device 76. For example, the signal acquisition module 113 acquires, from the light receiving element 94, an electrical signal depending on the intensity of light emitted from the processing liquid flow path 64 through which the processing liquid to be inspected among the processing liquid flow path forming mechanisms 62A to 62L. For example, the signal acquisition module 113 acquires an electrical signal having an amplitude (signal magnitude) depending on the intensity of the detection light. FIG. 9 is a diagram illustrating an example of an electrical signal acquired when a processing liquid per one time is supplied. In the example of FIG. 9, the horizontal axis represents time and the vertical axis represents the signal magnitude. The supply of the processing liquid per one time may be an operation from the start of discharge of the processing liquid by one of the nozzles 35A to 35L to a single wafer W until the discharge is completed. For example, in the supply of the processing liquid per one time by discharging the processing liquid from the nozzle 35A, the light receiving device 76 receives the light emitted from the processing liquid flow path 64 corresponding to the processing liquid flow path forming mechanism 62A when the radiation light is radiated from the radiation device 74. The signal acquisition module 113 outputs the acquired electrical signal to the condition determination support module 111.

For example, the display controller 114 (i.e., display circuitry) communicates bi-directionally with the condition determination support module 111. The display controller 114 may display, on a monitor MT, data calculated by the condition determination support module 111. The display controller 114 may receive data from the condition determination support module 111 according to a sequence of the condition determination support method to be described later and display the data on the monitor MT. Also, the display controller 114 may output, to the condition determination support module 111, information input by a user, such as an operator, on the monitor MT. Alternatively, the condition determination support module 111 may be equipped with a user input information acquisition device configured to acquire the information input by the user on the monitor MT. In this case, the user input information acquisition device may output the acquired information to the condition determination support module 111.

The condition determination support module 111 supports to determine conditions of whether to perform the recovery processing. For example, the condition determination support module 111 determines the conditions for performing the recovery processing and outputs the determined conditions to the foreign substance detection module 112. The condition determination support module 111 may determine not only the conditions of whether to perform the recovery processing but also determination conditions (calculation conditions) related to the conditions of whether to perform the recovery processing. The condition determination support module 111 is equipped with a data accumulator 115, a data extractor 116, a first foreign substance counter 117, an appropriateness evaluator 118, and a parameter calculator 119.

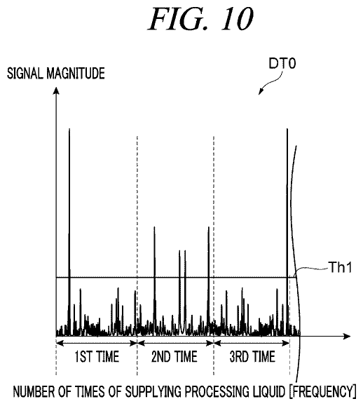

The data accumulator 115 accumulates electrical signals acquired by the signal acquisition module 113. The data accumulator 115 continuously accumulates the electrical signals acquired during the supply of the processing liquid per one time as illustrated in FIG. 9. A period in which the data accumulator 115 accumulates the electrical signals may be a period determined in advance by the operator. For example, the data accumulator 115 may accumulate the electrical signals acquired during a predetermined number of times of supplying the processing liquid. Alternatively, the data accumulator 115 may accumulate the electrical signals acquired within a predetermined time unit. The time unit may be, for example, a year, month, week or day. The data accumulated by the data accumulator 115 is referred to as “accumulation data”. The accumulation data is acquired by accumulating the intensity of emitted light at the time of radiating light to the processing liquid flow path 64 whenever the processing liquid is supplied to the wafer W. FIG. 10 is an example illustrating an example of accumulation data DT0. In the example of FIG. 10, the accumulation data DT0 is configured by accumulating electrical signals (data representing temporal changes in signal magnitude) acquired whenever the processing liquid is supplied.

The data extractor 116 extracts electrical signals acquired during a specific period from the accumulation data DT0 accumulated by the data accumulator 115. A specific period for an extraction target may be specified by the user. For example, the user may specify the specific period via the monitor MT. The specific period for the extraction target may be specified in terms of the number of times of processing with the processing liquid or in terms of time unit. In the example of FIG. 10, the accumulation data DT0 is extracted for a period specified in terms of the number of times of processing with the processing liquid. Some of the accumulation data extracted by the data extractor 116 is still referred to as accumulation data DT0.

The first foreign substance counter 117 counts foreign substances from the electrical signals extracted by the data extractor 116. The first foreign substance counter 117 counts the foreign substances whenever the processing liquid is supplied based on the intensity of emitted light at the time of radiating light to the processing liquid flow path 64. An example of counting the foreign substances by using the acquired electrical signals will be described with reference to FIG. 10. In the example of FIG. 10, the first foreign substance counter 117 counts, as a first count value, the number of times the signal magnitude exceeds a temporary threshold Th1 in each supply of the processing liquid per one time. For example, the temporary threshold Th1 is a provisional threshold for determining the conditions of whether to perform the recovery processing. The temporary threshold Th1 may be a value determined in advance based on the intensity of scattered light when the radiation light is scattered by the foreign substances in the processing liquid, or it may be a value specified by the user via the monitor MT.

The signal magnitude is correlated with a particle size of the foreign substance. As the particle size of the foreign substance increases, the signal magnitude increases, and as the particle size of the foreign substance decreases, the signal magnitude decreases. Therefore, if a threshold for counting the foreign substances is set too high (low sensitivity), some foreign substances may be missed. Conversely, if the threshold is set too low (high sensitivity), noise may be mistakenly counted as the foreign substances.

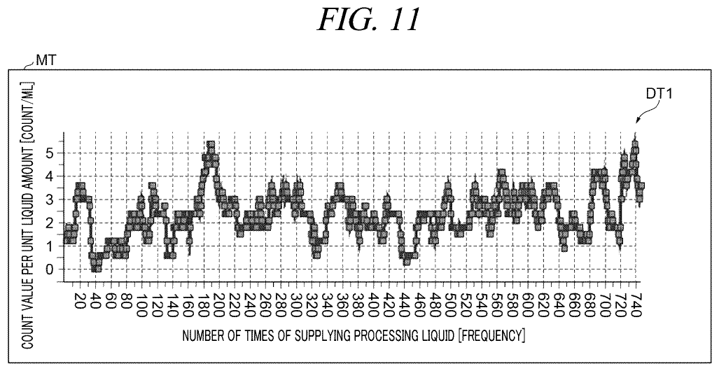

The first foreign substance counter 117 generates time series data from the first count values of the foreign substances. The time series data may be composed of the first count values arranged in chronological order, and is hereinafter referred to as “time series data”. The time series data is acquired by counting the foreign substances whenever the processing liquid is supplied to the wafer W, and arranged in chronological order. FIG. 11 is a graph illustrating an example of time series data DT1. The time series data DT1 may be represented as a graph with the horizontal axis indicating the number of times of supplying the processing liquid and the vertical axis indicating the first count value. FIG. 11 schematically illustrates the time series data DT1 displayed on the monitor MT. The vertical axis of the graph corresponding to the time series data DT1 may represent a count value per unit liquid amount which is acquired by dividing the first count value by the amount of liquid flown (discharged) when the processing liquid per one time is supplied. The first foreign substance counter 117 may output the time series data DT1 to the display controller 114, the appropriateness evaluator 118, and the parameter calculator 119.

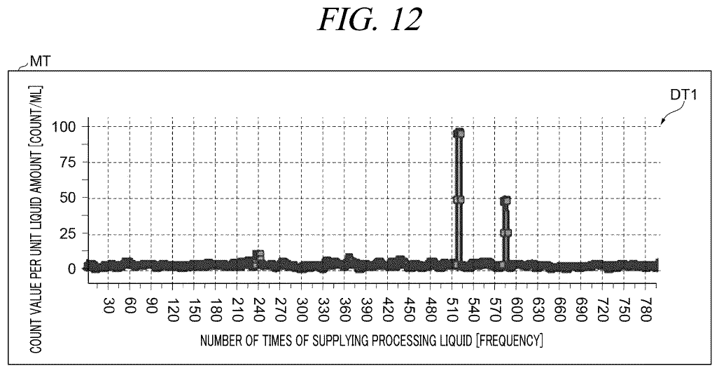

The appropriateness evaluator 118 inspects whether any fault value is included in the first count values of the time series data DT1. The appropriateness evaluator 118 may inspect whether any fault value is included in the first count values of the time series data DT1 through the statistical processing. For example, the appropriateness evaluator 118 inspects whether any fault value is included in the first count values by determining whether the time series data DT1 conforms to a Poisson distribution. In this case, the appropriateness evaluator 118 may calculate the probability of appearance of each count value of the foreign substances and perform the inspection based on the probability of appearance. Also, the appropriateness evaluator 118 may calculate a chi-square value for each count value of the foreign substances based on the probability of appearance and compare the sum of chi-square values with the probability of appearance of each count value of the foreign substances to inspect whether any fault value is included in the first count values. FIG. 12 is a graph illustrating an example of the time series data DT1 in a case where it is determined that the fault value is included in the first count values. FIG. 12 schematically illustrates the time series data DT1 displayed on the monitor MT when it is determined that the fault value is included. In the time series data DT1 shown in FIG. 12, a count value around the 520th supply and a count value around the 580th supply are abnormally high. In this case, for example, in the time series data DT1 shown in FIG. 12, the probability of appearance of an abnormal count value increases, which may cause an increase in the sum of chi-square values. Thus, it may be determined that the fault value is included in the first count values of the time series data DT1 shown in FIG. 12. In the following description, unless otherwise stated, it is assumed that any fault value is not included in the first count values of the time series data DT1.

The parameter calculator 119 calculates parameters required to determine conditions of whether to perform the recovery processing based on the accumulation data DT0. The parameters calculated by the parameter calculator 119 may include condition parameters that define the conditions of whether to perform the recovery processing as well as auxiliary parameters for determining the condition parameters. As illustrated in FIG. 8, the parameter calculator 119 is equipped with a detection particle size calculator 120, a sensitivity particle size calculator 121, a data update module 122, a threshold calculator 123, and a moving average number calculator 124.

The detection particle size calculator 120 calculates a detection particle size based on the accumulation data DT0. The detection particle size is the threshold of particle size (threshold of signal magnitude) used to determine whether to count particles as the foreign substances when the foreign substance detection module 112 counts and records the particles after the condition determination support module 111 determines the conditions of whether to perform the recovery processing. Although details will be described later, a count value of the detection particle size counted by the foreign substance detection module 112 as the threshold may not necessarily be used for determining the recovery processing. The count value of detection particle size counted as the threshold may be recorded in a count value recording unit within the foreign substance detection module 112.

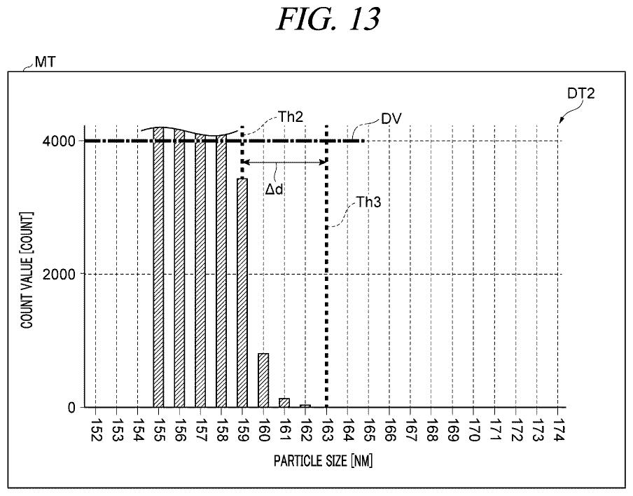

The detection particle size calculator 120 may calculate the detection particle size by referring to particle size data DT2 in which the count values of the foreign substances are arranged by particle size. For example, the particle size data DT2 may be generated by the first foreign substance counter 117 based on the accumulation data DT0. FIG. 13 is a graph (histogram) illustrating an example of the particle size data DT2. FIG. 13 schematically illustrates the particle size data DT2 displayed on the monitor MT. In the example of FIG. 13, the horizontal axis represents the particle size of the foreign substance and the vertical axis represents the count value. The particle size data DT2 may be generated as follows, but is not limited thereto. The first foreign substance counter 117 gradually increases the value of the temporary threshold Th1 by a predetermined increment (in the example of FIG. 13, increases the threshold of particle size by 1 nm), and repeatedly counts the foreign substances in the accumulation data DT0 based on each value of the temporary threshold Th1. In the example of FIG. 13, the first foreign substance counter 117 starts counting with an initial temporary threshold Th1 of 155 nm and then increases the temporary threshold Th1 to 156 nm, and repeatedly counts the foreign substances in the accumulation data DT0. The first foreign substance counter 117 repeatedly counts the foreign substances in the accumulation data DT0 while increasing the temporary threshold Th1 by 1 nm at a time. The first foreign substance counter 117 may repeat the counting within a predetermined threshold range of particle size (e.g., a range of 50 nm starting from the initial value of 155 nm) or may stop the counting when the count value reaches zero (0).

For example, in the particle size data DT2 shown in FIG. 13, a count value decreases as the particle size of the foreign substance increases. The detection particle size calculator 120 may determine, as a detection particle size Th2, a particle size which is first lower than a predetermined detection count value DV. For example, as illustrated in FIG. 13, when the detection count value DV is 4000, a particle size of 159 nm which is first lower than the detection count value DV may be set as the detection particle size Th2. Furthermore, in the particle size data DT2 shown in FIG. 13, when a minimum value of particle size (the temporary threshold Th1) for determining foreign substances is set to 159 nm and foreign substances are counted based on the accumulation data DT0, a count value is approximately 3300. The detection particle size calculator 120 outputs the calculated detection particle size Th2 to the sensitivity particle size calculator 121 and the foreign substance detection module 112.

The sensitivity particle size calculator 121 calculates a sensitivity particle size Th3 based on the accumulation data DT0. The sensitivity particle size Th3 is the threshold of particle size used to determine whether to count particles as the foreign substances when the foreign substance detection module 112 counts the particles and displays a count value on the monitor MT after the condition determination support module 111 determines the conditions of whether to perform the recovery processing. Although details will be described later, a count value of the sensitivity particle size Th3 counted by the foreign substance detection module 112 as the threshold may be used for determining the recovery processing. The count value of the sensitivity particle size Th3 counted as the threshold may be displayed on the monitor MT by the display controller 114. The sensitivity particle size Th3 is greater than the detection particle size Th2. The sensitivity particle size calculator 121 may calculate the sensitivity particle size Th3 based on the particle size data DT2. As illustrated in FIG. 13, the sensitivity particle size calculator 121 may determine, as the sensitivity particle size Th3, a value obtained by adding a predetermined increment Δd to the detection particle size Th2. Alternatively, the sensitivity particle size calculator 121 may determine, as the sensitivity particle size Th3, a value obtained by multiplying the detection particle size Th2 by n. Herein, n is a positive integer or a positive decimal. The sensitivity particle size calculator 121 outputs the calculated sensitivity particle size Th3 to the data update module 122 and the foreign substance detection module 112.

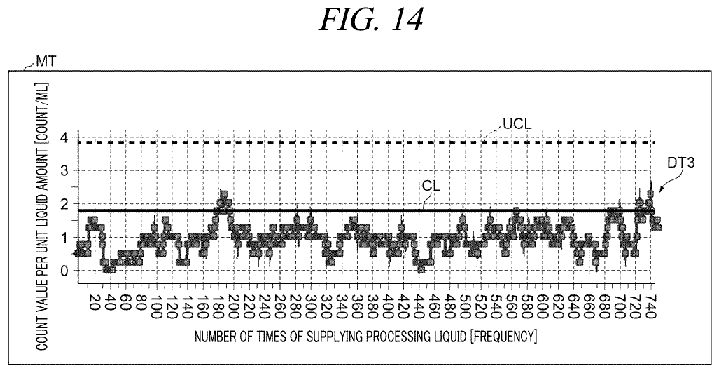

The data update module 122 generates updated time series data DT3 by updating the time series data DT1 with the sensitivity particle size Th3. For example, the data update module 122 may use the sensitivity particle size Th3 as a threshold and recount the foreign substances in each supply of the processing liquid by referring to the accumulation data DT0. The data update module 122 counts, as a second count value of foreign substances, the number of times the signal magnitude of the processing liquid exceeds the signal magnitude corresponding to the sensitivity particle size Th3 in each supply of the processing liquid. FIG. 14 is a graph illustrating an example of the updated time series data DT3. FIG. 14 schematically illustrates the updated time series data DT3 displayed on the monitor MT. In the example of FIG. 14, similar to the example of FIG. 11, the horizontal axis represents the number of times of supplying the processing liquid and the vertical axis represents the second count value (specifically, a count value per unit liquid amount which is acquired by dividing the second count value by the amount of liquid discharged when the processing liquid per one time is supplied). As illustrated in FIG. 14, the second count value of the foreign substances in the updated time series data DT3 is lower than the first count value of foreign substances in the time series data DT1 across all processing cycles. This is because of the sensitivity particle size Th3 being greater than the detection particle size Th2, which increases the sensitivity particle size Th3 to be greater than the temporary threshold Th1 and thus reduces the sensitivity of counting.

The threshold calculator 123 calculates a cleaning threshold that defines the conditions of whether to perform the recovery processing based on the updated time series data DT3. The threshold calculator 123 may first calculate a preliminary cleaning threshold CL. For example, the preliminary cleaning threshold CL may be calculated by the following Equation 1.

CL=AVG(DT3)×SR (1)

In Equation 1, AVG(DT3) represents an average of the second count values of the foreign substances in the updated time series data DT3, and SR represents a safety ratio. The safety ratio SR may be determined by the user. For example, the safety ratio SR may be set by the user based on the updated time series data DT3 displayed on the monitor MT by the display controller 114.

The threshold calculator 123 may calculate a cleaning threshold UCL based on the preliminary cleaning threshold CL. For example, the cleaning threshold UCL may be calculated by the following Equation 2.

UCL=CL+N1 (2)

In Equation 2, N1 represents an adjustment coefficient N1 and has a positive value. The adjustment coefficient N1 may be a value obtained by statistically processing the second count values in the updated time series data DT3. The adjustment coefficient N1 may also be a value three times the standard deviation of the second count values. The threshold calculator 123 outputs the preliminary cleaning threshold CL and the cleaning threshold UCL to the foreign substance detection module 112.

The moving average number calculator 124 calculates the number of data of moving average based on the updated time series data DT3. The number of data of moving average refers to a moving average number MV when comparing the cleaning threshold UCL with a moving average of count values of the foreign substances counted by the foreign substance detection module 112 based on the sensitivity particle size Th3. For example, the moving average number MV may be calculated by the following Equation 3.

MV=M1/AVG(DT3) (3)

In Equation 3, M1 represents an integer and has a positive value. The integer M1 may be previously determined. If the moving average number is large, it takes more iterations until an increase in count value is reflected in the moving average, which may delay the timing of performing the recovery processing. If the moving average number is small, it may be affected by the noise in the supply of the processing liquid per one time, which may delay the timing of performing the recovery processing. In one example, the integer M1 may be determined to appropriately adjust the timing of performing the recovery processing while avoiding these possibilities. The moving average number calculator 124 outputs the moving average number MV to the foreign substance detection module 112.

As described above, the parameters calculated by the parameter calculator 119 may include the detection particle size Th2, the sensitivity particle size Th3, the cleaning threshold UCL, and the moving average number MV. The cleaning threshold UCL and the moving average number MV are condition parameters that define the conditions of whether to perform the recovery processing. The detection particle size Th2 and the sensitivity particle size Th3 are auxiliary parameters used to determine the cleaning threshold UCL (or the cleaning threshold UCL and the moving average number MV) as the condition parameters.

The foreign substance detection module 112 performs a processing of detecting the foreign substances after the conditions of whether to perform the recovery processing are determined. The foreign substance detection module 112 determines whether to perform the recovery processing based on, for example, the cleaning threshold UCL calculated by the threshold calculator 123 and the moving average number MV calculated by the moving average number calculator 124. As illustrated in FIG. 8, the foreign substance detection module 112 is equipped with a third foreign substance counter 128, a count value recorder 129, a second foreign substance counter 125, a moving average calculator 126, and a recovery processing determiner 127.

In the third foreign substance counter 128, the detection particle size Th2 is input from the detection particle size calculator 120 and an electrical signal corresponding to the intensity of detection light is input from the signal acquisition module 113. The third foreign substance counter 128 uses a signal magnitude corresponding to the detection particle size Th2 as a threshold and counts foreign substances whenever the processing liquid is supplied. The third foreign substance counter 128 counts, as a third count value of foreign substances, the number of times the signal magnitude of the processing liquid exceeds the signal magnitude corresponding to the detection particle size Th2 in each supply of the processing liquid. The third foreign substance counter 128 outputs the third count value to the count value recorder 129.

The count value recorder 129 records the third count value. As described above, the third count value may not necessarily be used for determining the recovery processing. The count value recorder 129 may output the third count value to the outside, for example, upon user request. Alternatively, the count value recorder 129 may output the third count value to the display controller 114. The display controller 114 may display the third count value, as time series data or log data, on the monitor MT.

In the second foreign substance counter 125, the sensitivity particle size Th3 is input from the sensitivity particle size calculator 121 and an electrical signal corresponding to the intensity of detection light is input from the signal acquisition module 113. The second foreign substance counter 125 uses a signal magnitude corresponding to the sensitivity particle size Th3 as a threshold and counts foreign substances whenever the processing liquid is supplied. The second foreign substance counter 125 counts, as a fourth count value of foreign substances, the number of times the signal magnitude of the processing liquid exceeds the signal magnitude corresponding to the sensitivity particle size Th3 in each supply of the processing liquid. The fourth count value is output to the display controller 114, and the display controller 114 displays the fourth count value on the monitor MT.

In the moving average calculator 126, the moving average number MV is input from the moving average number calculator 124 and the fourth count value is input from the second foreign substance counter 125 in each supply of the processing liquid per one time. The moving average calculator 126 calculates a moving average of the fourth count values based on the moving average number MV and the most recent fourth count value. For example, the moving average calculator 126 calculates an average of the fourth count values from a data set including the most recent fourth count value and the recent fourth count values obtained when the processing liquid is supplied a plurality of number of times corresponding to the moving average number MV (more specifically, obtained from the same supply line).

In the recovery processing determiner 127, the cleaning threshold UCL is input from the threshold calculator 123 and a moving average is input from the moving average calculator 126 in each supply of the processing liquid per one time. The recovery processing determiner 127 compares the moving average of the fourth count values with the cleaning threshold UCL. For example, if the moving average of the fourth count values exceeds the cleaning threshold UCL, the recovery processing determiner 127 may determine that the recovery processing needs to be performed. When the recovery processing determiner 127 determines that the recovery processing needs to be performed, it may output a recovery processing instruction signal to, for example, the controller 100. Upon receiving the instruction signal, the controller 100 may control the liquid processing unit U1 or the like to supply the cleaning liquid to the flow path of the supply line, which is determined to be subjected to the recovery processing, among the supply lines 45A to 45L.

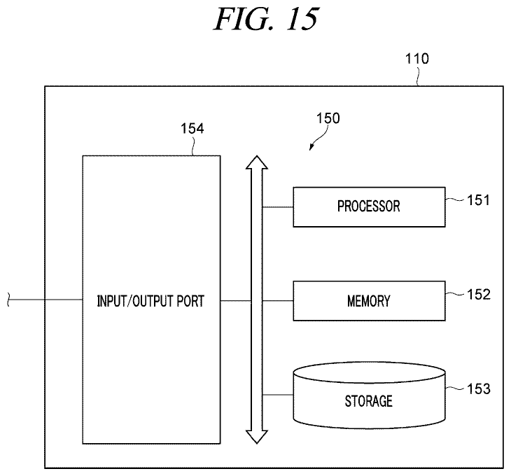

The controller 110 is composed of one or more control computers. FIG. 15 is a diagram illustrating an example of a hardware configuration of the controller 110. For example, the controller 110 is equipped with a circuit 150 shown in FIG. 15. The circuit 150 is equipped with one or more processors 151, a memory 152, a storage 153, and an input/output port 154. The storage 153 has a computer-readable recording medium such as a hard disk. The recording medium stores therein a program for allowing the controller 110 to implement the condition determination support method to be described later. The recording medium may be an extractable medium such as a non-volatile semiconductor memory, a magnetic disk or an optical disk.

The memory 152 temporarily stores therein the program loaded from the recording medium of the storage 153 and an operation result by the processor 151. The processor 151 constitutes the above-described individual functional modules by executing the program in cooperation with the memory 152. The input/output port 154 performs input/output of electrical signals between the parts of the processing station 3 in response to instructions from the processor 151.

The controller 110 may be composed of a plurality of control computers. For example, the foreign substance detection module 112 may be composed of one or more control computers and the condition determination support module 111 may be composed of another computer that can communicate with the one or more control computers. Also, the hardware configuration of the controller 110 is not necessarily limited to constituting the individual functional modules by the program. For example, the individual functional modules of the controller 110 may be composed of exclusive logical circuits or an ASIC (Application Specific Integrated Circuit) in which these logical circuits are integrated.

### [Condition Determination Support Method]

Hereinafter, an example of an operation of the controller 110 will be described. The controller 110 operates based on the condition determination support method performed by the condition determination support module 111 and a foreign substance detection method performed by the foreign substance detection module 112.

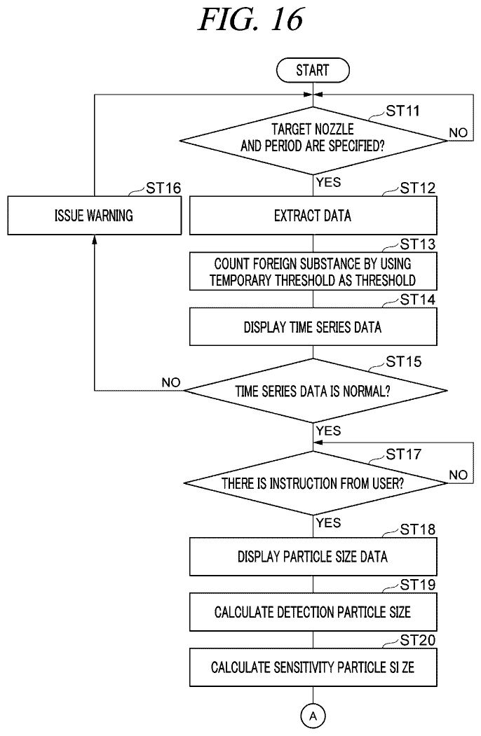

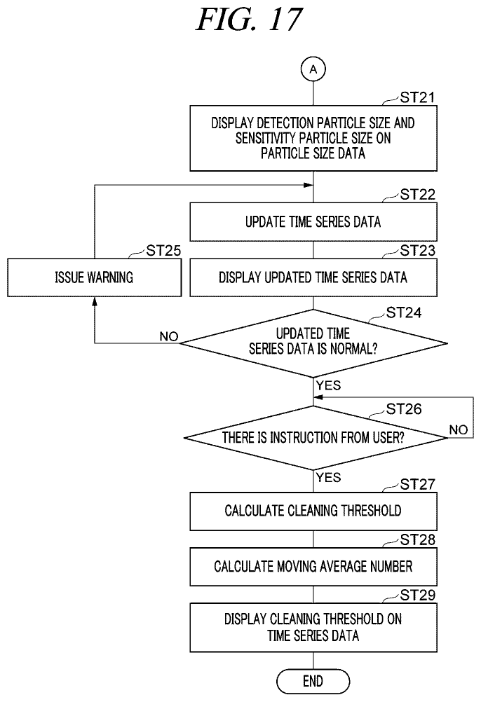

FIG. 16 and FIG. 17 are flowcharts illustrating examples of the condition determination support method. In the condition determination support method, processes ST11 to ST29 may be performed sequentially. In the condition determination support method, a parameter calculation process may be composed of a detection particle size calculation process (process ST19), a sensitivity particle size calculation process (process ST20), a threshold calculation process (process ST27), and a moving average number calculation process (process ST28).

First, in the process ST11, for example, the data extractor 116 determines whether a target nozzle and a period have been specified by the user. The data extractor 116 may receive the specification of one of the nozzles 32B to 32L as a nozzle to be supported (hereinafter referred to as “target nozzle”). The specification of the target nozzle (for which parameters are calculated) corresponds to the specification of the flow path for the processing liquid to be supported. The data extractor 116 may receive the specification of the period in terms of the number of times of processing with the processing liquid or in terms of time unit. For example, the target nozzle and the period may be specified by the user via the monitor MT. The display controller 114 may output the specified target nozzle and period to the data extractor 116.

Subsequently, in the process ST12, for example, the data extractor 116 extracts data corresponding to the target nozzle and the specified period from the data accumulated by the data accumulator 115. Hereinafter, the remaining accumulation data after being extracted by the data extractor 116 is also simply referred to as “accumulation data”.

Then, in the process ST13, for example, the first foreign substance counter 117 counts the foreign substances in the accumulation data extracted by the data extractor 116. For example, the first foreign substance counter 117 counts, as the first count value of foreign substances, the number of times the signal magnitude exceeds the temporary threshold Th1 in each supply of the processing liquid per one time.

Thereafter, in the process ST14 (display control process), for example, the display controller 114 displays the time series data DT1, which has been generated from the first count value, on the monitor MT. The time series data DT1 is generated from the first count value of foreign substances by the first foreign substance counter 117 and output to the display controller 114 and then displayed on the monitor MT.

Subsequently, in the process ST15 (appropriateness evaluation process), for example, the appropriateness evaluator 118 inspects whether any fault value is included in the first count values of the time series data DT1. During the inspection by the appropriateness evaluator 118, the display controller 114 may display the time series data DT1 on the monitor MT (see FIG. 11 and FIG. 12). When the first count values of the time series data DT1 include the fault value and are determined as being abnormal (process ST15: NO), the appropriateness evaluator 118 issues a warning to the user in the process ST16. In the process ST16, for example, the appropriateness evaluator 118 may output a warning signal to the display controller 114 and the display controller 114 may display the warning on the monitor MT. After the process ST16, the condition determination support method restarts from the process ST11. In the new process ST11, for example, the data extractor 116 determines whether a target nozzle and a period have newly been specified by the user.

When the first count values of the time series data DT1 do not include the fault value and are determined as being normal (process ST15: YES), the detection particle size calculator 120 determines whether there is an instruction from the user in the process ST17. Until the instruction is received from the user, the detection particle size calculator 120 does not calculate the detection particle size Th2 (process ST17: NO). That is, the detection particle size calculator 120 may wait for the instruction from the user before calculating the detection particle size Th2. Herein, the instruction from the user refers to, for example, the instruction from the user to proceed to a processing of calculating the detection particle size Th2. For example, the instruction from the user may be input by the user via the monitor MT and output to the detection particle size calculator 120 by the display controller 114.

When there is the instruction from the user (process ST17: YES), the display controller 114 may display the particle size data DT2, which has been generated based on the accumulation data DT0, on the monitor MT in the process ST18 (display control process). The particle size data DT2 is generated by the first foreign substance counter 117, which has received the instruction from the detection particle size calculator 120, and output to the display controller 114 and then displayed by the display controller 114.

Subsequently, in the process ST19 (detection particle size calculation process), for example, the detection particle size calculator 120 calculates the detection particle size Th2. The detection particle size calculator 120 may calculate the detection particle size Th2 based on the particle size data DT2. An example of the calculation of the detection particle size Th2 will be described with reference to FIG. 13. As described above, the detection particle size calculator 120 may determine, as the detection particle size Th2, a particle size which is first lower than the detection count value DV based on the particle size data DT2. Instead of this calculation method, the detection particle size calculator 120 may set an upper limit of first count value and determine, as the detection particle size Th2, a particle size at which the first count value begins to decrease from the upper limit. In the example of FIG. 13, the upper limit of first count value is set to 4000. In this example, the first count value exceeds 4000 up to the particle size of 158 mm, but is lower than 4000 at the particle size of 159 mm. From the particle size greater than 159 mm, the first count value continues to decrease. Accordingly, the detection particle size calculator 120 may determine, as the detection particle size Th2, the particle size greater than 159 mm.

Then, in the process ST20 (sensitivity particle size calculation process), for example, the sensitivity particle size calculator 121 calculates the sensitivity particle size Th3. The sensitivity particle size calculator 121 may calculate the sensitivity particle size Th3 based on the particle size data DT2. An example of the calculation of the sensitivity particle size Th3 will be described with reference to FIG. 13. As described above, the sensitivity particle size calculator 121 may determine, as the sensitivity particle size Th3, a value obtained by adding the increment Δd to the detection particle size Th2. Alternatively, the sensitivity particle size calculator 121 may determine, as the sensitivity particle size Th3, a value obtained by multiplying the detection particle size Th2 by n. Instead of these methods, the sensitivity particle size calculator 121 may determine, as the sensitivity particle size Th3, a particle size at which a decrease rate of first count value is within a predetermined range. In the example of FIG. 13, the first count value starts to decrease from the particle size greater than 159 mm, and approaches zero (0) with converging changes in decrease rate from the particle size greater than 163 mm. Accordingly, the sensitivity particle size calculator 121 may determine, as the sensitivity particle size Th3, the particle size greater than 163 mm.

Thereafter, in the process ST21 illustrated in FIG. 17, for example, the display controller 114 displays the detection particle size Th2 and the sensitivity particle size Th3 to be overlapped with the particle size data DT2 on the monitor MT. For example, the display controller 114 may highlight particle sizes corresponding to the detection particle size Th2 and the sensitivity particle size Th3.

Subsequently, in the process ST22 (data update process), the data update module 122 generates the updated time series data DT3 by updating the time series data DT1 based on the sensitivity particle size Th3. For example, the data update module 122 may use the signal magnitude corresponding to the sensitivity particle size Th3 as the threshold and recount the foreign substances (i.e., count the second count value) in each supply of the processing liquid by referring to the accumulation data DT0. After the process ST22, the data update module 122 may output the updated time series data DT3 to the display controller 114. In the process ST23, the display controller 114 displays the updated time series data DT3 on the monitor MT.

Then, in the process ST24, for example, the appropriateness evaluator 118 inspects whether any fault value is included in the second count values of the updated time series data DT3. In the process ST24, for example, the data update module 122 may output the updated time series data DT3 to the appropriateness evaluator 118. The appropriateness evaluator 118 may output the inspection result to the data update module 122. The appropriateness evaluator 118 may inspect whether any fault value is included in the second count values of the updated time series data DT3 through the statistical processing. For example, the appropriateness evaluator 118 inspects whether any fault value is included in the second count values by determining whether the updated time series data DT3 conforms to the Poisson distribution.

When the second count values of the updated time series data DT3 include the fault value and are determined as being abnormal (process ST24: NO), the appropriateness evaluator 118 issues the warning to the user in the process ST25. After the process ST25, the condition determination support method restarts from the process ST22. In the new process ST22, for example, the data update module 122 may receive the specification of a period newly selected by the user. Then, the data update module 122 may recount the second count value of foreign substances in each supply of the processing liquid for the new period.

When the second count values of the updated time series data DT3 do not include the fault value and are determined as being normal (process ST24: YES), the threshold calculator 123 determines whether there is the instruction from the user in the process ST26. Until the instruction is received from the user, the threshold calculator 123 may not calculate the cleaning threshold UCL (process ST26: NO). That is, the threshold calculator 123 may wait for the instruction from the user before calculating the cleaning threshold UCL. Herein, the instruction from the user refers to, for example, the instruction from the user to proceed to the processing of calculating the cleaning threshold UCL.

When there is the instruction from the user (process ST26: YES), for example, the threshold calculator 123 calculates the cleaning threshold UCL, which defines the conditions of whether to perform the recovery processing, in the process ST27 (threshold calculation process). The threshold calculator 123 may calculate the cleaning threshold UCL based on the average of the second count values of foreign substances in the updated time series data DT3 and the safety ratio SR specified by the user. Then, in the process ST28 (moving average number calculation process), for example, the moving average number calculator 124 calculates the moving average number MV. The moving average number calculator 124 may calculate the moving average number MV by using the average of the second count values of foreign substances in the updated time series data DT3.

Thereafter, in the process ST29, for example, the display controller 114 displays the cleaning threshold UCL and the preliminary cleaning threshold CL to be overlapped with the updated time series data DT3 on the monitor MT (see FIG. 14). The cleaning threshold UCL and the preliminary cleaning threshold CL displayed on the monitor MT may be adjusted by the user (the processes ST27 to ST29 may be repeated). For example, when the safety ratio SR is input by the user via the monitor MT, the cleaning threshold UCL and the preliminary cleaning threshold CL may change depending on the safety ratio SR. The cleaning threshold UCL and the preliminary cleaning threshold CL may be adjusted based on changes in the safety ratio SR. The condition determination support method is completed with the process ST29.

### [Foreign Substance Detection Method]

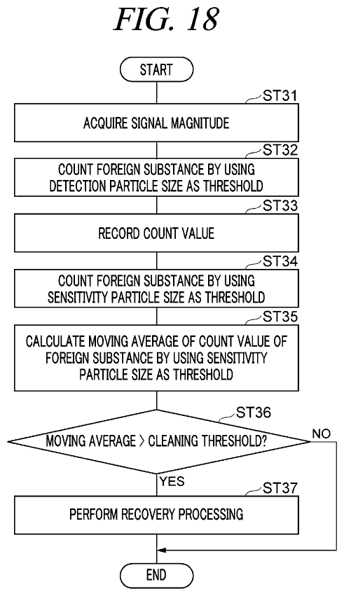

FIG. 18 is a flowchart illustrating an example of a foreign substance detection method. In the foreign substance detection method, processes ST31 to ST36 may be performed sequentially as the processing liquid per one time is supplied. First, in the process ST31, for example, the second foreign substance counter 125 and the third foreign substance counter 128 acquire the electrical signal depending on the intensity of the detection light from the signal acquisition module 113.

Subsequently, in the process ST32, the third foreign substance counter 128 counts the foreign substances with reference to the signal magnitude corresponding to the detection particle size Th2, which has been calculated in the process ST19, as the threshold. The third foreign substance counter 128 counts, as the third count value of foreign substances, the number of times the signal magnitude exceeds the signal magnitude corresponding to the detection particle size Th2. Then, in the process ST33, the count value recorder 129 records the third count value, and the third count value may not necessarily be used for determining the recovery processing.

Thereafter, in the process ST34, for example, the second foreign substance counter 125 counts the foreign substances with reference to the signal magnitude corresponding to the sensitivity particle size Th3, which has been calculated in the process ST20, as the threshold. The second foreign substance counter 125 counts, as the fourth count value of foreign substances, the number of times the signal magnitude of the processing liquid exceeds the signal magnitude corresponding to the sensitivity particle size Th3. Then, in the process ST35, for example, the moving average calculator 126 calculates the moving average of the fourth count values based on the moving average number MV calculated in the process ST28 and the recent fourth count value calculated in the process ST34.

Subsequently, in the process ST36, for example, the recovery processing determiner 127 compares the moving average calculated in the process ST35 with the cleaning threshold UCL calculated in the process ST27. When the moving average does not exceed the cleaning threshold UCL (process ST36: NO), the foreign substance detection processing method at the time of supplying the processing liquid per one time is ended without performing a process ST37. When the moving average exceeds the cleaning threshold UCL (process ST36: YES), the recovery processing determiner 127 may determine that the recovery processing needs to be performed. When the recovery processing determiner 127 determines that the recovery processing needs to be performed, it may output a recovery processing instruction signal to, for example, the controller 100.

The display controller 114 may display the calculation result, such as the fourth count value, on the monitor MT during at least a part of the processes ST34 to ST36. In the foreign substance detection processing method illustrated in FIG. 18, the processes ST34 to ST36 are not limited to being performed after the processes ST31 and ST32, but may also be performed simultaneously with the processes ST31 and ST32. The foreign substance detection method is completed with the process ST36 or ST37.

### Operations and Effects

If the recovery processing is to be performed to the flow path of the processing liquid in the wafer processing system, it is necessary to determine the timing of performing the recovery processing, i.e., the conditions of whether to perform the recovery processing. For example, it is assumed that the operator analyzes the actual result of counting foreign substances by the foreign substance detection module and then sets the conditions of whether to perform the recovery processing. In this regard, in the above-described condition determination support apparatus and condition determination support method, the parameters required to determine the conditions of whether to perform the recovery processing of cleaning the processing liquid flow path in the wafer processing system 1 are calculated automatically. In this case, the conditions may be determined automatically by using the automatically calculated parameters, or may be determined by the operator based on the automatically calculated parameters. Therefore, the operator can easily determine the conditions of whether to perform the recovery processing. Also, even if the apparatus autonomously determines the parameters, it performs operations based on instructions from the operator, which is equivalent to the case where the operator determines the parameters.

The parameter calculator 119 may be equipped with the detection particle size calculator 120 configured to calculate the detection particle size Th2, which is the threshold of particle size for determining whether to count the particles as the foreign substances, based on the accumulation data DT0 when determining the conditions and counting and recording the foreign substances. In this case, the detection particle size calculator 120 may calculate the appropriate value of the detection particle size Th2 based on the trend of the accumulation data DT0. Thus, it is possible to count the foreign substances with appropriate sensitivity.

The parameter calculator 119 may also be equipped with the sensitivity particle size calculator 121 configured to calculate the sensitivity particle size Th3, which is the threshold of particle size for determining whether to count the particles as the foreign substances and is greater than the detection particle size Th2, based on the accumulation data DT0 when determining the conditions and counting and displaying the foreign substances. In this case, by calculating the sensitivity particle size Th3 when counting and displaying the foreign substances in addition to the detection particle size Th2, it is possible to perform the counting of the foreign substances suitable for recording and the counting of the foreign substances suitable for display.

The condition determination support module 111 may also be equipped with the data update module 122 configured to generate the updated time series data DT3 by updating, with the sensitivity particle size Th3, the time series data DT1 of the count values obtained by counting the foreign substances whenever the processing liquid is supplied to the wafer W. Further, the parameter calculator 119 may be equipped with the threshold calculator 123 configured to calculate the cleaning threshold UCL, which defines the conditions, based on the updated time series data DT3. In this case, the cleaning threshold UCL is calculated based on the trend of the count values of the foreign substances over time. Furthermore, the cleaning threshold UCL is calculated based on the updated time series data DT3 from which the foreign substances are detected with appropriate sensitivity. Therefore, it is possible to calculate the cleaning threshold UCL with high accuracy.

The parameter calculator 119 may also be equipped with the moving average number calculator 124 configured to calculate the number of data (moving average number MV) of moving average when comparing the moving average of the count values of the foreign substances obtained by using the sensitivity particle size Th3 with the cleaning threshold UCL based on the updated time series data DT3. In this case, the moving average number MV is calculated based on the trend of the count values of the foreign substances over time. Further, the moving average number MV is calculated based on the updated time series data DT3 from which the foreign substances are detected with appropriate sensitivity. Therefore, it is possible to calculate the moving average number MV with high accuracy.

The condition determination support module 111 may also be equipped with the appropriateness evaluator 118 configured to inspect whether any fault value is included in the count values of the foreign substances of the time series data DT1, and the display controller 114 configured to display the time series data DT1 on the monitor MT during the inspection by the appropriateness evaluator 118. In this case, the degree of accuracy in calculating parameters is improved by previously inspecting whether any fault value is included. Further, the operator can easily determine the presence or absence of the fault value.

The condition determination support module 111 may also be equipped with the display controller 114 configured to display, on the monitor MT, the particle size data DT2 in which the first count values of the foreign substances are arranged by the particle size based on the accumulation data DT0 when the detection particle size calculator 120 calculates the detection particle size Th2. In this case, the operator can easily understand the relationship between the detection particle size Th2 and the particle size data DT2.

The detection particle size calculator 120 and the threshold calculator 123 may calculate the detection particle size Th2 and the cleaning threshold UCL, respectively, after receiving the instruction from the user. In this case, the process is performed after appropriately waiting for the instruction from the user serving as the operator, and, thus, the operator can track the progress of the support process.

The threshold calculator 123 may calculate the average of the second count values of the foreign substances of the updated time series data DT3 and the cleaning threshold UCL based on the value obtained by multiplying the average by the safety ratio SR set by the user. In this case, the cleaning threshold UCL changes depending on the safety ratio SR, and, thus, the user (operator) can have the discretion to determine the cleaning threshold UCL.

The condition determination support module 111 may also be equipped with the appropriateness evaluator 118 configured to inspect whether any fault value is included in the first count values of the foreign substances of the time series data DT1. The detection particle size calculator 120 may calculate the detection particle size Th2 after the inspection by the appropriateness evaluator 118. The sensitivity particle size calculator 121 may calculate the sensitivity particle size Th3 after the inspection by the appropriateness evaluator 118. The threshold calculator 123 may calculate the cleaning threshold UCL after the sensitivity particle size calculator 121 calculates the sensitivity particle size Th3. In the condition determination support module 111, the cleaning threshold UCL can be calculated by the standardized calculation method by operating the appropriateness evaluator 118, the detection particle size calculator 120, the sensitivity particle size calculator 121, and the threshold calculator 123 in a predetermined order.

The parameter calculation process may include the detection particle size calculation process (process ST19) of calculating the detection particle size Th2, which represents the threshold of the particle size for determining whether to count the particles as the foreign substances, based on the accumulation data DT0 determining the conditions and counting and recording the foreign substances. In this case, the appropriate value of the detection particle size Th2 can be calculated based on the trend of the accumulation data DT0. Thus, it is possible to count the foreign substances with appropriate sensitivity.

The parameter calculation process may further include the sensitivity particle size calculation process (process ST20) of calculating the sensitivity particle size Th3, which is the threshold of the particle size for determining whether to count the particles as the foreign substances and is greater than the detection particle size Th2, based on the accumulation data DT0 when determining the conditions and counting and displaying the foreign substances. In this case, by calculating the sensitivity particle size Th3 when counting and displaying the foreign substances in addition to the detection particle size Th2, it is possible to perform the counting of foreign substances suitable for recording and the counting of foreign substances suitable for display.

The condition determination support method may further include the process ST22 of generating the updated time series data DT3 by updating, with the sensitivity particle size Th3, the time series data DT1 of the count values obtained by counting the foreign substances whenever the processing liquid is supplied to the wafer W. The parameter calculation process may also include the threshold calculation process (process ST27) of calculating the cleaning threshold UCL, which defines the conditions, based on the updated time series data DT3 obtained by updating the time series data DT1 with the sensitivity particle size Th3. In this case, the cleaning threshold UCL is calculated based on the trend of the count values of the foreign substances over time. Furthermore, the cleaning threshold UCL is calculated based on the updated time series data DT3 from which the foreign substances are detected with appropriate sensitivity. Therefore, it is possible to calculate the cleaning threshold UCL with high accuracy.

The parameter calculation process may further include the moving average number calculation process (process ST28) of calculating the number of data of the moving average when comparing the moving average of the count values of the foreign substances obtained by using the sensitivity particle size Th3 with the cleaning threshold UCL based on the updated time series data DT3. In this case, the moving average number MV is calculated based on the trend of the count values of the foreign substances over time. Further, the moving average number MV is calculated based on the updated time series data DT3 from which the foreign substances are detected with appropriate sensitivity. Therefore, it is possible to calculate the moving average number MV with high accuracy.

The condition determination support method may include the appropriateness evaluation process (process ST15) of inspecting whether any fault value is included in the count values of the foreign substances of the time series data DT1, and the display control process (process ST14) of displaying the time series data DT1 on the monitor MT during the inspection in the appropriateness evaluation process. In this case, the degree of accuracy in calculating the parameters is improved by previously inspecting whether any fault value is included. Further, the operator can easily determine the presence or absence of the fault value.

The condition determination support method may also include the display control process (step ST18) of displaying, on the monitor MT, the particle size data DT2 in which the first count values of the foreign substances are arranged by the particle size based on the accumulation data DT0 when calculating the detection particle size Th2 in the detection particle size calculation process (process ST19). In this case, the operator can easily understand the relationship between the detection particle size Th2 and the particle size data DT2.

In the detection particle size calculation process (process ST19), the detection particle size Th2 may be calculated after receiving the instruction from the user, and in the threshold calculation process (process ST27), the cleaning threshold UCL may be calculated after receiving the instruction from the user. In this case, the process is performed after appropriately waiting for the instruction from the user serving as the operator, and, thus, the operator can track the progress of the support process.

In the threshold calculation process (process ST27), the average of the second count values of the foreign substances of the updated time series data DT3 may be calculated and the cleaning threshold UCL may be calculated based on the value obtained by multiplying the average by the safety ratio SR set by the user. In this case, the cleaning threshold UCL changes depending on the safety ratio SR, and, thus, the user (operator) can have the discretion to determine the cleaning threshold UCL.

The condition determination support method may also include the appropriateness evaluation process (process ST15) of inspecting whether any fault value is included in the first count values of the foreign substances of the time series data DT1. In the detection particle size calculation process (process ST19), the detection particle size Th2 may be calculated after the inspection in the appropriateness evaluation process. In the sensitivity particle size calculation process (process ST20), the sensitivity particle size Th3 may be calculated after the inspection in the appropriateness evaluation process. In the threshold calculation process (process ST27), the cleaning threshold UCL may be calculated after the sensitivity particle size Th3 is calculated in the sensitivity particle size calculation process. In the condition determination support method, the cleaning threshold UCL can be calculated by the standardized calculation method by performing the appropriateness evaluation process, the detection particle size calculation process, the sensitivity particle size calculation process, and the threshold calculation process in a predetermined order.

### Modification Example

While various one or more embodiments of the present disclosure have been described above, various additions, omissions, substitutions and changes may be made without being limited to the one or more embodiments of the present disclosure described above. The controller 110 may be located outside the housing 52. That is, the controller 110 may be provided as a separate device from the foreign substance detection module 50 in the wafer processing system 1. The condition determination support module 111 may not be included in the controller 110. Alternatively, the condition determination support module 111 may be provided within the controller 100 or provided as a control medium located outside the processing station. In this case, the control medium may be, for example, a cloud system.

In the condition determination support method illustrated in FIG. 16 and FIG. 17, some processes may be omitted. In the condition determination support method, the processes of displaying data on the monitor MT by the display controller 114 (processes ST14, ST18, ST21, ST23 and ST29) may be omitted. In the condition determination support method, the processes of determining whether there is the instruction from the user (processes ST17 and ST26) may also be omitted.

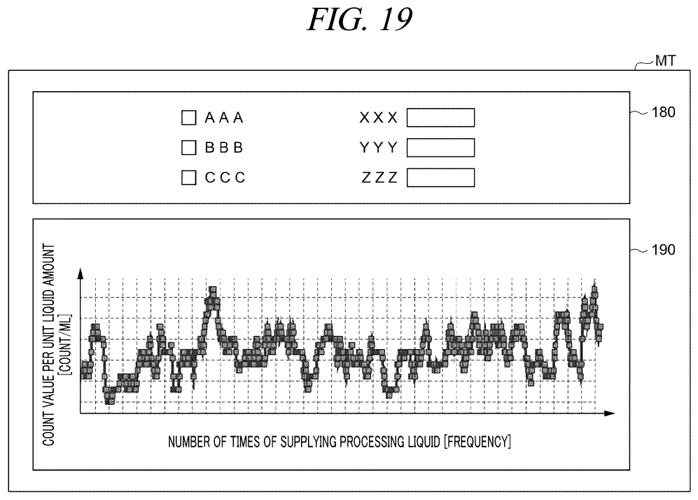

Each of FIG. 19 to FIG. 21 schematically illustrates an example of information displayed on the monitor MT by the display controller 114 while the condition determination support method is performed. The display controller 114 may display, on the monitor MT, a region where a graph of the time series data DT1 is depicted and a region where the user can configure parameters for adjusting the display format of the graph. Hereinafter, the region for configuring parameters will be referred to as “first region 180” and the region where the graph is depicted will be referred to as “second region 190”. On the monitor MT, the first region 180 may be displayed above the second region 190.

The content displayed in the first region 180 and the second region 190 may change depending on the progress of the condition determination support method or based on an instruction from the user. When the content in the first region 180 and the second region 190 changes, the size of each region may also be adjusted accordingly. Each of the first region 180 and the second region 190 may be defined by borders as a part of the screen on the monitor MT (see FIG. 19). However, only the content may be displayed without explicitly showing borders defining those regions.

In the example of FIG. 19, the display controller 114 displays, in the second region 190, a graph of sample data (e.g., the time series data DT1) referenced for condition determination support. Herein, the display controller 114 also displays, in the first region 180, a field (i.e., an input screen) for configuring parameters related to the display of the sample data graph. Configurable parameters in this case may include the specification of file data containing the sample data and time ranges within the data, and entries specifying display subjects, such as specific conditions (e.g., a predetermined detection value. Extraction of data containing this detection value).

Other examples of the configurable parameters include whether to adopt a moving average, foreign substance detection sensitivity for display (e.g., the temporary threshold Th1), and graph configuration items, such as units for respective axes. Further, the configurable parameters may include the display of a lower detection limit at the time of acquiring data to be displayed on the graph, conditions (i.e., recovery conditions) for determining the recovery processing at the present time and an average, and whether to display these parameters. FIG. 19 schematically illustrates the first region 180, which functions as a screen for configuring parameters related to display. For example, a display that allows the user to select options via checkboxes may be provided, or a display that allows the user to input numerical values may be provided.

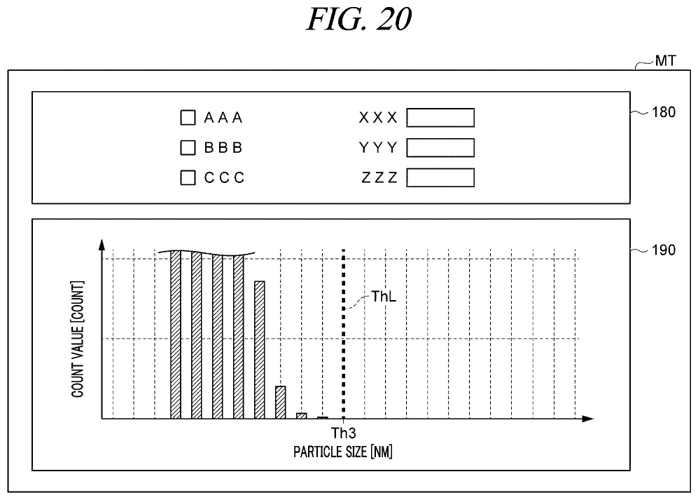

In the example of FIG. 20, the display controller 114 displays, in the second region 190, a graph that represents count values for respective particle sizes (i.e., a graph related to the particle size data DT2). Herein, the display controller 114 also displays, in the first region 180, a field (i.e., an input screen) for configuring parameters related to the display of the graph of count values for respective particle sizes. Configurable parameters in this case may include the display of temporary detection particle size and sensitivity particle size at the present time, conditions of whether to perform the recovery processing, or parameters (e.g., the preliminary cleaning threshold CL) related to those conditions.

Some of the items explained in the example of FIG. 19 may also be displayed on the screen illustrated in FIG. 20. In the screen shown in FIG. 20, the detection particle size Th2 and the sensitivity particle size Th3 are calculated and set while the graph shown in FIG. 19 is appropriately switched to a different display format. The display controller 114 may display a line Th1 indicating the sensitivity particle size Th3 on the graph in the second region 190.

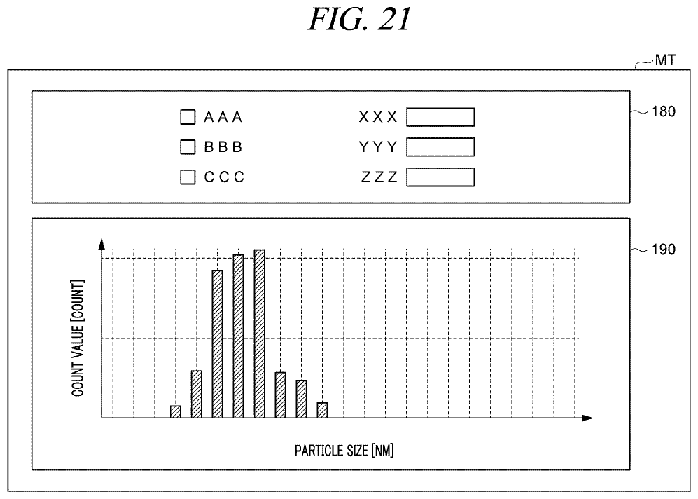

In the example of FIG. 21, the display controller 114 displays, in the first region 180, a field (i.e., an input screen) for configuring parameters to determine the conditions of whether to perform the recovery processing. Examples of the parameters include an upper threshold of count values, a lower threshold of count values, a allowable ratio (i.e., the safety rate (SR)), and the adjustment coefficient N1. In the second region 190, the graph is switched to a different display format from the graph shown in FIG. 20 based on the determination of the display controller 114 or the user's instruction regarding the instruction items for switching in the first region 180. Further, in the example of FIG. 21, the graph displayed in the second region 190 is not limited to a graph representing the relationship between particle size and count value.

According to the present disclosure, the condition determination support apparatus and the condition determination support method are capable of enabling the operator to easily determine the conditions for performing the recovery processing of cleaning the flow path within the substrate processing apparatus.

From the foregoing, it will be appreciated that various one or more embodiments of the present disclosure of the present disclosure have been described herein for purposes of illustration and various changes can be made without departing from the scope and spirit of the present disclosure. Accordingly, various one or more embodiments of the present disclosure described herein are not intended to be limiting, and the true scope and spirit are indicated by the following claims.

We claim:

1. A condition determination support apparatus, comprising:
a foreign substance detector including:
a processing liquid flow path connected to a flow path through which a processing liquid flows within a substrate processing apparatus and connecting a source to a nozzle;
a measurer including:
a light source configured to generate laser light as radiation light;
a movable radiation device configured to radiate the radiation light to the processing liquid flow path; and
a light receiver configured to receive light emitted from the processing liquid in response to the radiation light being radiated to the processing liquid flow path; and
circuitry including a parameter calculator configured to:
calculate parameters required to determine the conditions of whether to perform a recovery processing of cleaning the flow path to remove foreign substances from the flow path based on accumulation data acquired from the light receiver.

2. The condition determination support apparatus of claim 1,
wherein the parameter calculator includes a detection particle size calculator configured to calculate a detection particle size, which is a threshold of particle size used to determine whether to count particles as foreign substances, based on the accumulation data when the foreign substances are counted and recorded after the determination of the conditions.

3. The condition determination support apparatus of claim 2,
wherein the parameter calculator further includes a sensitivity particle size calculator configured to calculate a sensitivity particle size, which is a threshold of the particle size used to determine whether to count the particles as the foreign substances and is greater than the detection particle size, based on the accumulation data when the foreign substances are counted and displayed after the determination of the conditions.

4. The condition determination support apparatus of claim 3, wherein the circuitry further includes:
a data update module configured to generate updated time series data by updating time series data of count values, which is acquired by counting the foreign substances whenever the processing liquid is supplied to the substrate, with the sensitivity particle size,
wherein the parameter calculator further includes a threshold calculator configured to calculate a cleaning threshold that defines the conditions based on the updated time series data.

5. The condition determination support apparatus of claim 4,
wherein the parameter calculator further includes a moving average number calculator configured to calculate a number of data of a moving average based on the updated time series data when comparing the cleaning threshold with the moving average of the count values of the foreign substances based on the sensitivity particle size.

6. The condition determination support apparatus of claim 1, further comprising:
an appropriateness evaluator configured to inspect whether a fault value is included in count values of the foreign substances of time series data acquired by counting the foreign substances whenever the processing liquid is supplied to the substrate; and
a display circuitry configured to display the time series data on a monitor while being inspected by the appropriateness evaluator.

7. The condition determination support apparatus of claim 2, further comprising:
a display circuitry configured to display, on a monitor, particle size data in which count values of the foreign substances are arranged by the particle size based on the accumulation data while the detection particle size calculator calculates the detection particle size.

8. The condition determination support apparatus of claim 4,
wherein the detection particle size calculator waits for an instruction from a user and calculates the detection particle size, and
the threshold calculator waits for an instruction from the user and calculates the cleaning threshold.

9. The condition determination support apparatus of claim 4,
wherein the threshold calculator calculates an average of the count values of the foreign substances of the updated time series data, and calculates the cleaning threshold based on a value obtained by multiplying the average by a safety ratio set by a user.

10. The condition determination support apparatus of claim 4, further comprising:
an appropriateness evaluator configured to inspect whether a fault value is included in the count values of the foreign substances of the time series data,
wherein the detection particle size calculator calculates the detection particle size after being inspected by the appropriateness evaluator,
the sensitivity particle size calculator calculates the sensitivity particle size after being inspected by the appropriateness evaluator, and
the threshold calculator calculates the cleaning threshold after the sensitivity particle size calculator calculates the sensitivity particle size.

11. A condition determination support method, comprising:
measuring, by a foreign substance detector, foreign substances in a flow path, through which a processing liquid flows within a substrate processing apparatus, the measuring including:
connecting a processing liquid flow path to the flow path to connect a source to a nozzle;
generating, by a light source of a measurer, laser light as radiation light;
radiating, by a movable radiation device of the measurer, the radiation light to the processing liquid flow path; and
receiving, by a light receiver of the measurer, light emitted from the processing liquid in response to the radiation light being radiated to the processing liquid flow path; and
calculating, using circuitry, parameters required to determine the conditions of whether to perform a recovery processing of cleaning the flow path to remove foreign substances from the flow path based on accumulation data acquired from the light receiver.

12. The condition determination support method of claim 11,
wherein the calculating of the parameters includes calculating a detection particle size, which is a threshold of particle size used to determine whether to count particles as foreign substances, based on the accumulation data when the foreign substances are counted and recorded after the determination of the conditions.

13. The condition determination support method of claim 12,
wherein the calculating of the parameters further includes calculating a sensitivity particle size, which is a threshold of particle size used to determine whether to count particles as foreign substances and is greater than the detection particle size, based on the accumulation data when the foreign substances are counted and displayed after the determination of the conditions.

14. The condition determination support method of claim 13, further comprising:
generating, by the circuitry, updated time series data by updating time series data of count values, which is acquired by counting the foreign substances whenever the processing liquid is supplied to the substrate, with the sensitivity particle size,
wherein the calculating of the parameters further includes calculating a cleaning threshold that defines the conditions based on the updated time series data.

15. The condition determination support method of claim 14,
wherein the calculating of the parameters further includes calculating a number of data of a moving average based on the updated time series data when comparing the cleaning threshold with the moving average of the count values of the foreign substances based on the sensitivity particle size.

16. The condition determination support method of claim 11, further comprising:
inspecting, by the circuitry, whether a fault value is included in count values of the foreign substances of time series data acquired by counting the foreign substances whenever the processing liquid is supplied to the substrate; and
displaying the time series data on a monitor during the inspecting of whether the fault value is included.

17. The condition determination support method of claim 12, further comprising:
displaying, on a monitor, particle size data in which count values of the foreign substances are arranged by the particle size based on the accumulation data during the calculating of the detection particle size.

18. The condition determination support method of claim 14,
wherein in the calculating of the detection particle size, the detection particle size is calculated after receiving an instruction from a user, and
in the calculating of the cleaning threshold, the cleaning threshold is calculated after receiving an instruction from the user.

19. The condition determination support method of claim 14,
wherein in the calculating of the cleaning threshold, an average of the count values of the foreign substances of the updated time series data is calculated, and the cleaning threshold is calculated based on a value obtained by multiplying the average by a safety ratio set by a user.

20. The condition determination support method of claim 14, further comprising:
inspecting, by the circuitry, whether a fault value is included in the count values of the foreign substances of the time series data,
wherein in the calculating of the detection particle size, the detection particle size is calculated after the inspecting of whether the fault value is included,
in the calculating of the sensitivity particle size, the sensitivity particle size is calculated after the inspecting of whether the fault value is included, and
in the calculating of the cleaning threshold, the cleaning threshold is calculated after the calculating of the sensitivity particle size.
